(19) United States
(12) Patent Application Publication
(10) Pub. No.: US 2010/0147492 A1
(43) Pub. Date: Jun. 17, 2010

(54) IGBT cooling method

(76) Inventor: Ronald David Conry, Tallahassee, FL (US)

Correspondence Address: J. Wiley Horton, Esquire;Pennington, Moore, Wilkinson, Bell & Dunbar, P.A., Post Office Box 10095, Tallahassee, FL, 32302-2095, US

(21) Appl. No.: 12/653,237

(22) Filed: Dec. 10, 2009

Related U.S. Application Data
(60) Provisional application No. 61/201,393, filed on Dec. 10, 2008.

(51) Int. Cl. H01L 23/44; F28D 15/00

(52) U.S. Cl. 165/104.19; 165/104.31; 165/104.33; 165/108

(57) ABSTRACT

A method for cooling power electronic devices such as IGBT's. The method comprises placing the IGBT board in a containment structure and flooding the containment with circulating liquid refrigerant. The liquid refrigerant is boiled within the containment and the resulting gas is then removed for continued circulation within a heat engine. The phase change of the refrigerant provides excellent cooling properties. In addition, the ability to place the cooling medium directly over the IGBT's themselves represents a significant advantage.

### CROSS-REFERENCES TO RELATED APPLICATIONS

This is a non-provisional patent application claiming the benefit of an earlier-filed provisional application. The provisional application was assigned Ser. No. 61/201,393. It was filed on Dec. 10, 2008 and listed the same inventor.

### STATEMENT REGARDING FEDERALLY SPONSORED RESEARCH OR DEVELOPMENT

Not Applicable.

### MICROFICHE APPENDIX

Not Applicable

### BACKGROUND OF THE INVENTION

1. Field of the Invention

The present invention relates to the field of power electronics. More specifically, the invention comprises a method for cooling heat-generating power electronic devices such as insulated gate bipolar transistors (“IGBT's”).

2. Description of the Related Art

IGBT's have become increasingly common in the past two decades. The “third generation” of these devices have become so efficient, fast, and rugged, that they have replaced more traditional high-power switching devices. IGBT's handle a relatively high power density by connecting a dozen or more individual gates in parallel.

The increasing power density of such devices has pushed traditional electronic cooling strategies to their limits, if not beyond. FIG. 1 shows a typical circuit board incorporating IGBT's. IGBT board 10—in this particular example—contains 24 individual IGBT's 12. The IGBT's are connected using board traces, jumper wiring, and/or other suitable conducting devices. The IGBT board is connected to control circuitry for controlling the switching operations. Power input and output leads are also provided. However, those skilled in the art will know that the majority of the heat produced in the device originates within each individual IGBT.

While the present invention is in no way limited to any particular size or configuration of IGBT, it may be useful to the reader to understand the scale of the devices. An IGBT as shown in FIG. 1 might measure approximately 8 mm square and only 1.5 mm thick. A large amount of heat is generated in this small volume. IGBT's now feature excellent longevity, provided that they are adequately cooled. The removal of heat from such a small volume is a challenge.

FIGS. 2 and 3 depict traditional cooling methods used in power electronics. FIG. 2 shows an elevation view of IGBT board 10 attached to heat sink 18. The IGBT's often switch voltages in the range of 200V to 600 V. The IGBT board must possess suitable insulating properties. These boards are often made of ceramic. The individual IGBT's are “built” on the upward facing surface face of this ceramic substrate (with respect to the orientation sown in the view). The IGBT's are often created using masking and deposition methods familiar to those skilled in the art of electronics manufacturing.

FIG. 2 shows the IGBT board including ceramic substrate 14 with IGBT's 12 on its upper face and copper plate 16 being deposited on its lower face. The directional terms “upper and “lower” refer to the orientation shown in the view. The reader should bear in mind that some circuit boards are oriented differently—including vertically. A more generalized nomenclature for the two sides of the IGBT board would therefore be to refer to the upper face as shown in FIG. 2 as the “IGBT side” and the lower face as the “back side.” Copper plate 16 is often added to improve thermal conductivity between the back side of the IGBT board and heat sink 18.

Studying this structure the reader will appreciate a significant problem. The heat is generated on the IGBT side of the IGBT board, and the primary heat removal device is located on the back side. The heat generated by the IGBT's must travel through the ceramic substrate before reaching the dissipating device.

FIG. 3 shows a known approach for increasing the heat removal rate. Heat sink 24 includes a plurality of coolant passages 26, through which a coolant (such as water or a cooled gas) is forced. Retaining bracket 20 includes a plurality of fingers 22 which firmly press the IGBT board against heat sink 24. Of course, the heat generated by the IGBT's must still pass through the ceramic substrate before it can be dissipated by heat sink 24. Thus, a temperature spike occurring in the IGBT's (and thus on the IGBT side of the IGBT board) will persist for a significant time period no matter how well heat sink 24 dissipates heat on the back side of the IGBT board. This fact represents a significant problem with the existing cooling technology.

Before proceeding to a discussion of the current invention, the reader may wish to know a few more details regarding components which are typically found in close proximity to the IGBT board (since such components must be considered when designing a cooling device). FIG. 4 shows a greatly simplified depiction of a power switching device. IGBT board 10 lies on heat sink 24. Retaining bracket 20 holds the IGBT board in position. The retaining bracket often includes electrical connections for the low-power switching signals and the high-power switched signals.

Control electronics board 28 provides the low-power switching signals which control the gate functions of each individual IGBT. It is preferably located near the IGBT board. Many more components would be included in an actual power switching device, including the input and output power lines and an encompassing housing. As these are not particularly significant to the present invention, they have not been shown.

It is common to connect 2 or more assemblies such as shown in FIG. 4 in parallel in order to increase current capacity. A single housing might contain four or more such assemblies. A single control electronics board might then “feed” all the IGBT boards.

### BRIEF SUMMARY OF THE INVENTION

The present invention is a method for cooling power electronic devices such as IGBT's. The method comprises placing the IGBT board in a containment structure and flooding the containment with circulating liquid refrigerant. The liquid refrigerant is boiled within the containment and the resulting gas is then removed for continued circulation within a heat engine. The phase change of the refrigerant provides excellent cooling properties. In addition, the ability to place the cooling medium directly over the IGBT's themselves represents a significant advantage.

### BRIEF DESCRIPTION OF THE SEVERAL VIEWS OF THE DRAWINGS

FIG. 1 is a perspective view, showing a representative prior art IGBT board.

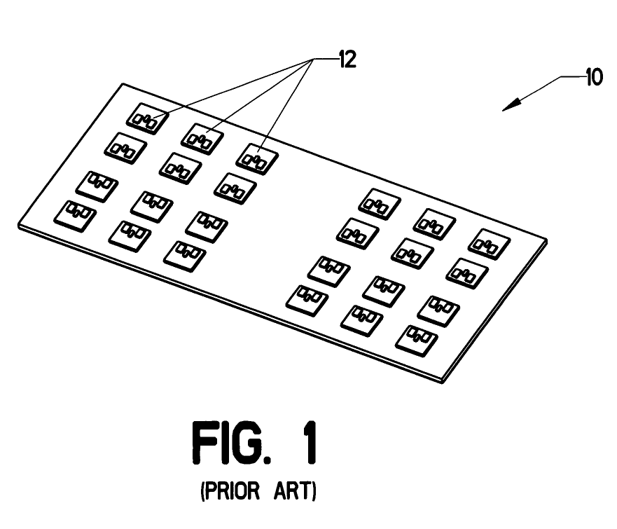

FIG. 2 is an elevation view, showing a prior art IGBT board attached to a heat sink.

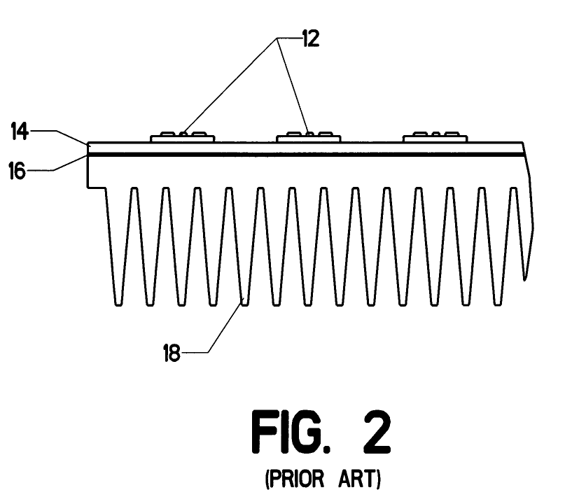

FIG. 3 is an elevation view, showing a prior art IGBT board attached to a heat sink with internal cooling passages.

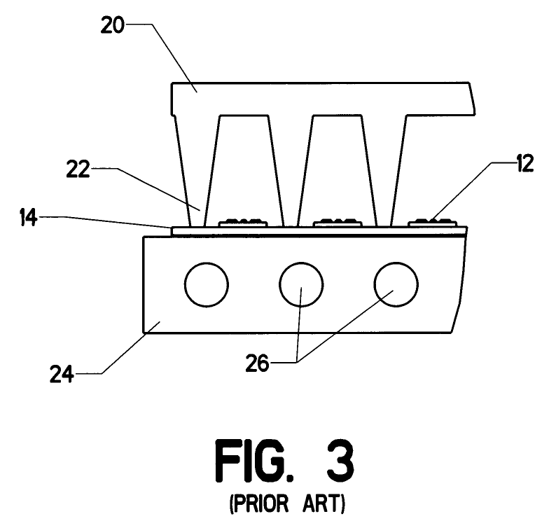

FIG. 4 is a perspective view, showing a simplified depiction of components typically found in close proximity to an IGBT board.

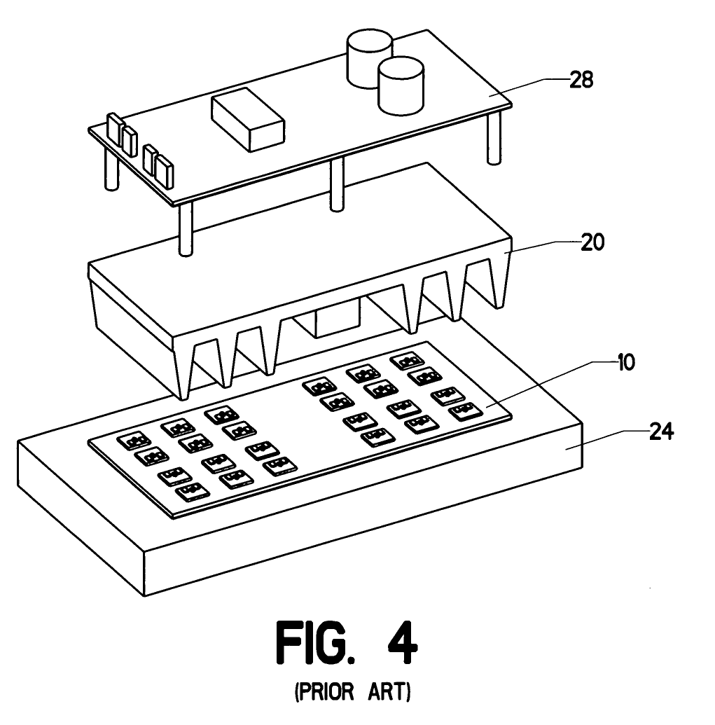

FIG. 5 is a perspective view, showing a representative cooling containment as used in the present invention.

FIG. 6 is an elevation view, showing an IGBT board and associated components placed in the cooling containment and flooded with coolant.

FIG. 7 is a perspective view with a cutaway, showing the addition of a serpentine coolant channel to the cooling containment.

FIG. 8 is an elevation view with a partial section, showing the location of the serpentine coolant channel with respect to the IGBT board.

FIG. 9 is a perspective view with a cutaway, showing the addition of parallel coolant channels to the cooling containment.

FIG. 10 is a detailed elevation view with a partial section, showing the location of the parallel coolant channels with respect to the IGBT board and—in addition—the optional inclusion of parallel coolant channels on the IGBT-side of the IGBT board.

FIG. 11 is a perspective view, showing an alternate embodiment for the retaining bracket which includes fluid passages and injectors.

FIG. 12 is an elevation view with a partial section, showing how the alternate retaining bracket of FIG. 11 cools the IGBT's.

FIG. 13 is an elevation view, showing a cooling containment configured for a vertically-oriented IGBT board.

### REFERENCE NUMERALS IN THE DRAWINGS

| | | | |
|---|---|---|---|
| 10 | IGBT board | 12 | IGBT |
| 14 | ceramic substrate | 16 | copper plate |
| 18 | heat sink | 20 | retaining bracket |
| 22 | finger | 24 | heat sink |
| 26 | coolant passage | 28 | control electronics board |
| 30 | containment | 32 | cover |
| 34 | coolant inlet | 36 | floor |
| 37 | coolant outlet | 38 | wall |
| 40 | solenoid valve | 42 | level sensor |
| 44 | critical level sensor | 46 | serpentine channel |
| 48 | channel feed | 50 | channel exit |
| 52 | cross flow channel | 54 | bracket channel |
| 56 | alternate retaining bracket | 58 | coolant inlet |
| 60 | coolant manifold | 62 | injector |

### DETAILED DESCRIPTION OF THE INVENTION

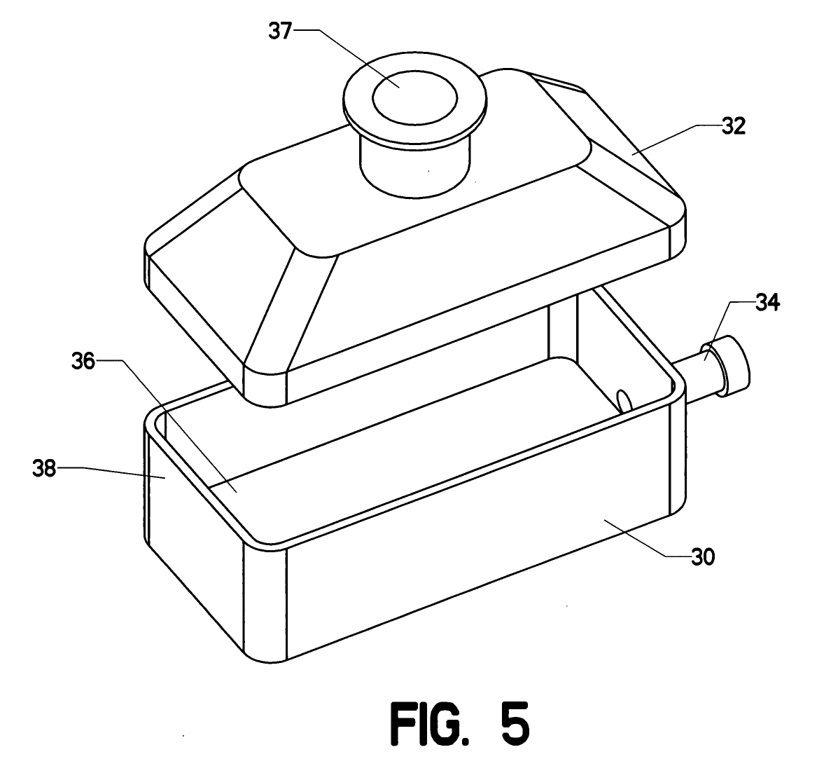

The present invention proposes cooling an IGBT board by flooding it with boiling refrigerant. An enclosure must therefore be provided around the IGBT board to contain the liquid refrigerant. Such an enclosure could assume an endless variety of forms. However, for purposes of providing an exemplary embodiment, FIG. 5 shows containment 30 with a corresponding cover 32. Coolant inlet 34 is provided for the admission of liquid refrigerant. Coolant outlet 37 is provided for the evacuation of gaseous refrigerant. In the particular example shown, containment 30 includes floor 36 and a surrounding wall 38.

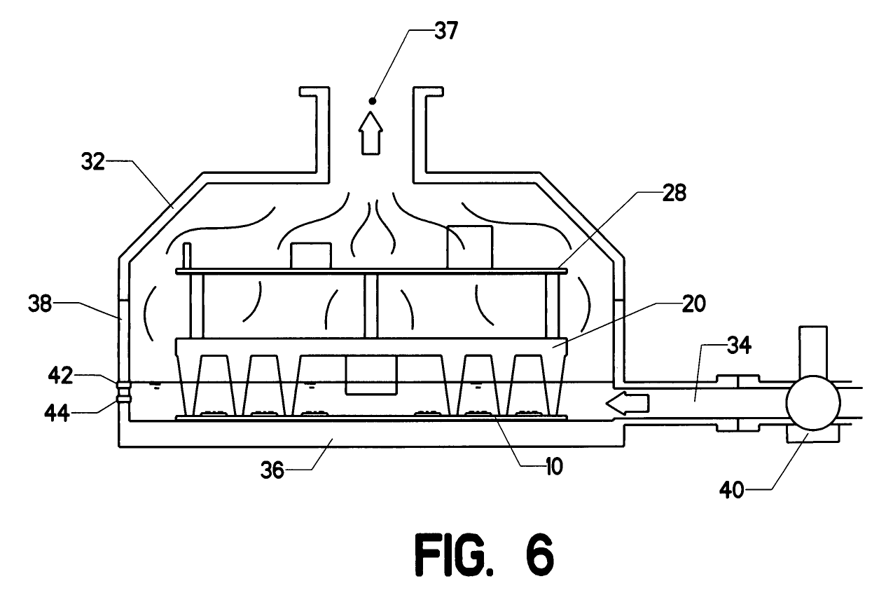

FIG. 6 shows a completed assembly using the containment of FIG. 5. IGBT board 10 is placed on floor 36 and held in position by retaining bracket 20. Control electronics board 28 is attached to the retaining bracket or some other suitable fixture. A metering device such as a solenoid valve, an electronic expansion valve, or a thermostatic valve is used to control the flow of liquid refrigerant into the containment. In the example shown in FIG. 6, solenoid valve 40 controls the flow.

As sensing device is used to sense the level of refrigerant within the containment and this information is then used to regulate the metering device. Level sensor 42 is one example of how this could be done. In this specific example, level sensor 42 is a device which changes state when it is covered by liquid refrigerant. This information is fed to a control system which adjusts the refrigerant metering device.

The refrigerant employed is preferably a known refrigerant such as is used in HVAC systems. The refrigerant selected should have high thermal conductivity but low electrical conductivity. It also must not significantly degrade the electrical components within the containment (whether in the liquid or gaseous state). R-134a is one suitable example.

The refrigerant is circulated in a conventional cooling cycle, which would typically include a compressor, an evaporator, and a condenser, as well as other components. The containment shown in FIG. 6 serves as the evaporator. Liquid refrigerant is pumped in up to the level of level sensor 42. The heat supplied by the power electronic devices boils the refrigerant and converts it to a gas. The gas is evacuated through coolant outlet 37 and returned—directly or indirectly—to the compressor.

When the level of liquid refrigerant falls below level sensor 42, solenoid valve 40 is opened and more liquid refrigerant is pumped in. The compressor in such a system may also be triggered by the operation of the solenoid valve, so that the compressor is only running while new refrigerant is being pumped in. On the other hand, some embodiments might use a tap or auxiliary loop of a much larger HVAC system. In such an embodiment, the compressor might be operating independently of the operation of the solenoid valve.

It is preferable to keep the IGBT's covered in liquid refrigerant in order to minimize temperature spikes. Critical level sensor 44 is provided to detect a minimum level of refrigerant for safe operation. In some applications, the IGBT's will sit idle for extended periods. The flow of refrigerant will cease in these periods and the containment will eventually be devoid of liquid refrigerant. When the IGBT's start back up, they will not have the cooling benefit of the liquid refrigerant. Thus, they are preferably operated at a limited power level until the refrigerant flow can commence. Once the IGBT's are covered in liquid refrigerant, the power level can be ramped up.

Critical level sensor 44 is one example of a sensing technique that could be used to transition from the low-power starting routine to high-power operations. Once it sense the fact that the containment has been flooded to its level, the transition could commence.

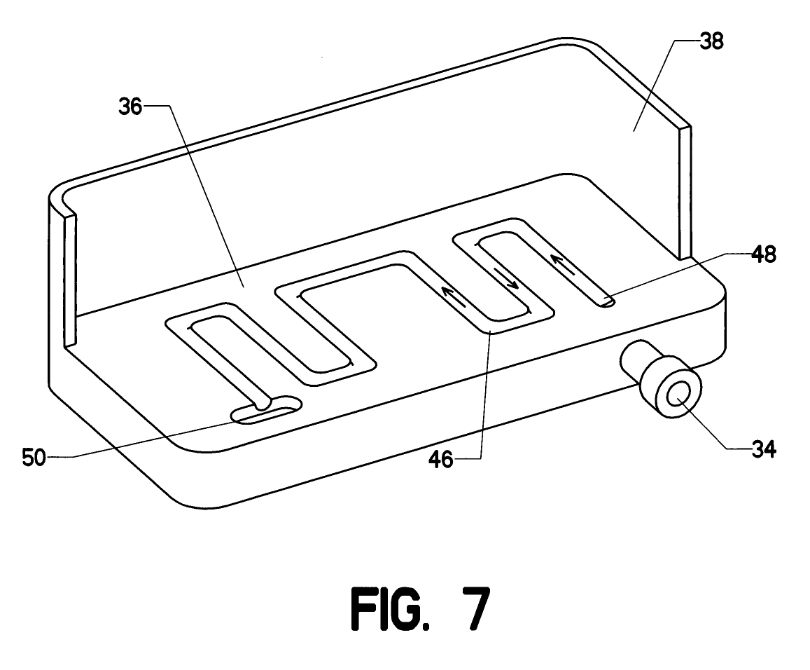

The simple flooded containment of FIG. 6 provides significantly enhanced cooling. Additional features can be added to further enhance the cooling. FIG. 7 shows a modified containment 30 containing serpentine channel 46. In the embodiment shown, the top of the serpentine channel is closed by the IGBT board itself, which rests on floor 36. Coolant inlet 34 feeds liquid refrigerant into the serpentine channel, where it flows linearly until reaching channel exit 50. At the channel exit it escapes to flood the containment up to the level of level sensor 42.

In another embodiment the IGBT board could be inverted so that the IGBT's themselves protrude downward into the serpentine channel. In still other embodiments the serpentine channel could be completely enclosed within the floor itself and the direction of flow depicted in FIG. 7 could be reversed.

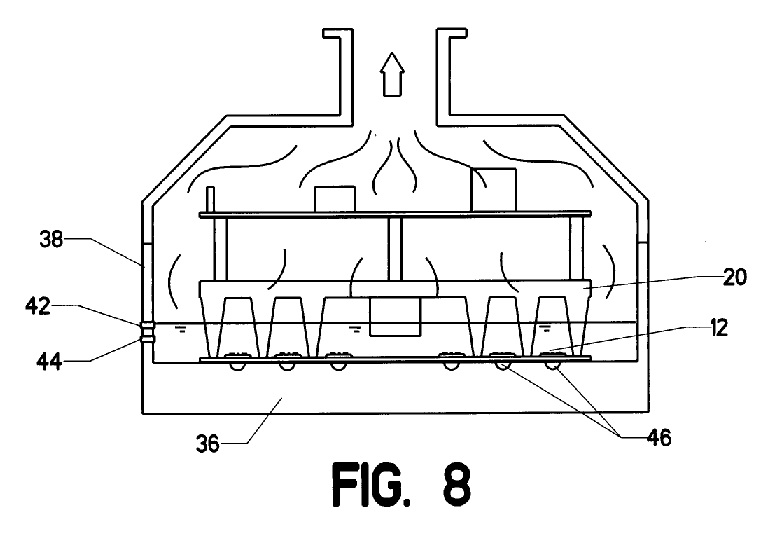

FIG. 8 is an elevation view of a completed assembly with a section through the containment to show the location of the serpentine channel. The reader will observe how each lateral passage of serpentine channel 46 passes directly beneath an IGBT 12. The reader will also observe how the IGBT board itself forms the top of the serpentine channel. The use of this enhancement increases the removal of heat from the back side of the IGBT board. Removal of heat from the IGBT side is made directly to the boiling refrigerant itself.

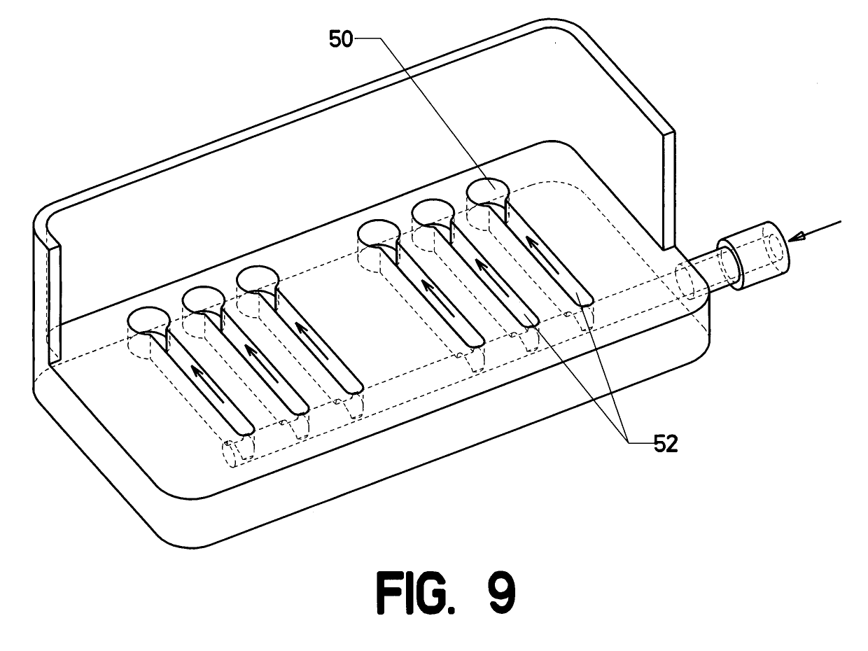

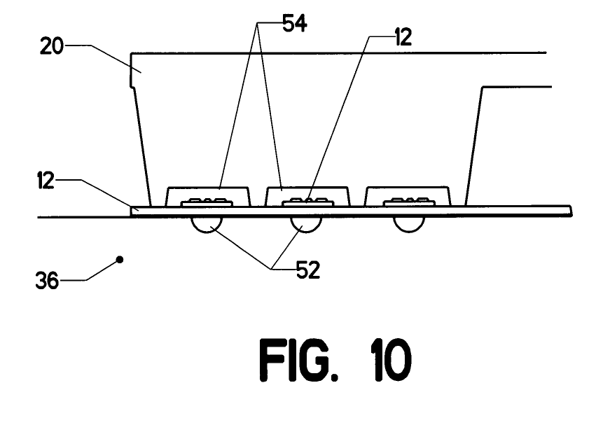

FIG. 9 shows another approach to removing heat from the back side of the IGBT board. A plurality of parallel cross flow channels 52 are used. Each channel is fed independently from the coolant inlet and each channel terminates in its own channel exit 50. FIG. 10 shows a sectioned elevation view of these cross flow channels 52 with the IGBT board 12 in place. The reader will observe how each cross flow channel lies directly beneath an IGBT.

FIG. 10 shows still another refinement. Retaining bracket 20 has been modified to include a plurality of parallel bracket channels 54 passing directly over the top of the IGBT's. Liquid refrigerant is fed into the modified retaining bracket and forced to flow through bracket channels 54 in a direction which is normal to the page. Thus, in this embodiment, both the IGBT side and the back side of the IGBT board is actively cooled.

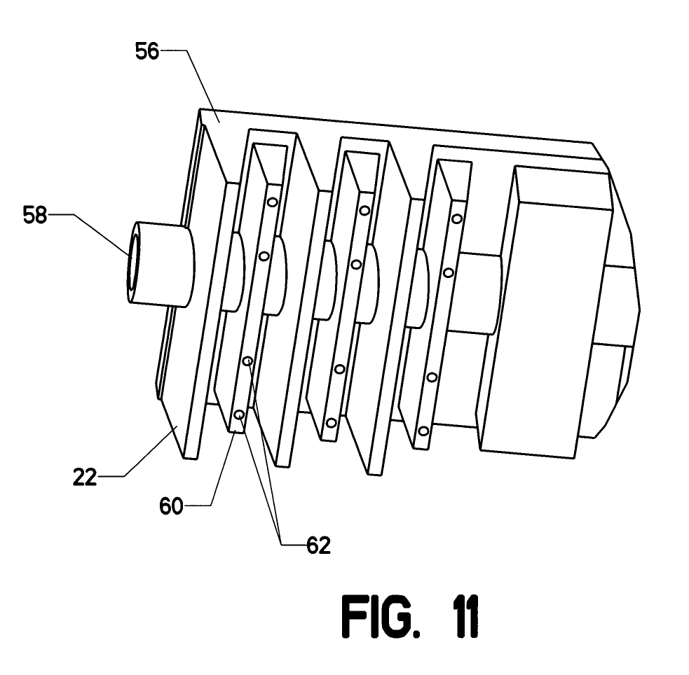

FIG. 11 illustrates yet another approach to cooling the IGBT's. Alternate retaining bracket 56 includes coolant inlet 58. Internal passages connect coolant inlet 58 to a plurality of coolant manifolds 60. Each coolant manifold—in turn—includes a plurality of injectors 60. Each injector is positioned directly over an IGBT.

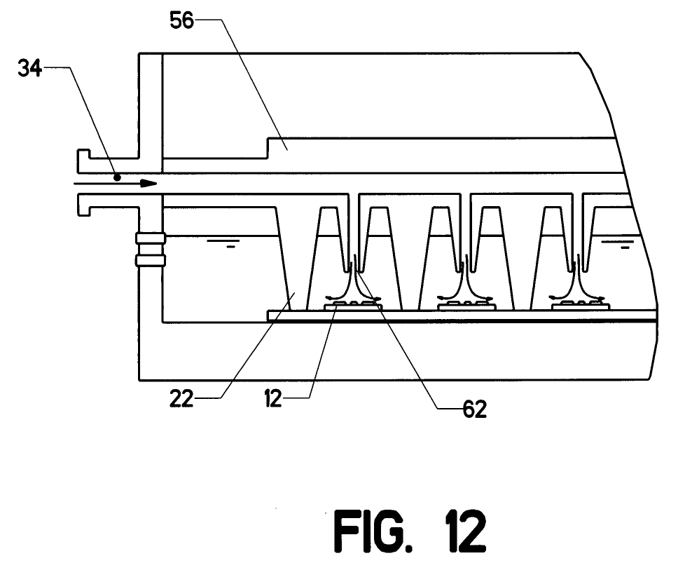

FIG. 12 is a sectioned elevation view with alternate retainer bracket 56 in position over an IGBT board. The reader will observe how each injector 62 forces liquid refrigerant directly against an IGBT. After impinging upon an IGBT, the liquid refrigerant flows outward into the flooded containment. It is also possible in this embodiment to use a reduced refrigerant charge and omit the flooding of the containment. The injectors can spray the refrigerant directly onto the IGBT's at a rate which vaporizes the refrigerant without leaving any significant amount of liquid refrigerant in the bottom of the containment.

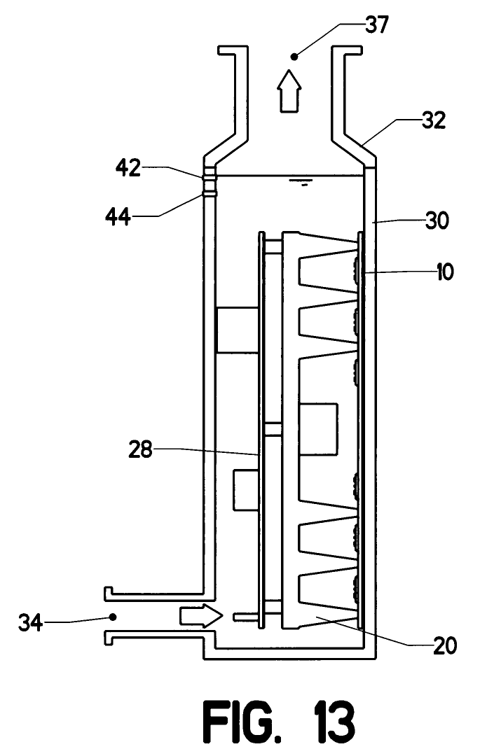

These illustrated examples demonstrate how a variety of designs can be used to pass liquid refrigerant over or near the IGBT's and flood the containment. Numerous other possibilities have not been illustrated. FIG. 13, as one additional example, shows a configuration that is well suited to a vertically-oriented IGBT board. This configuration is well suited to vehicle applications, where the sloshing of the liquid refrigerant due to the motion of the vehicle is a concern.

Coolant inlet 34 selectively fills the containment with liquid refrigerant up to the level of level sensor 42. As the refrigerant boils, gaseous refrigerant is evacuated through coolant outlet 37. The reader will note that control electronics board 28 is immersed within the liquid refrigerant in this embodiment. This is a possibility for all the embodiments illustrated (depending upon the height of flooding selected in the design). On the other hand, in some embodiments it may be desirable to place the control electronics board outside the containment and pass the electrical connections between the control electronics board and the IGBT board through the containment.

While IGBT's have been used as an example of a power electronic device in need of cooling, the invention is by no means limited to those devices. It could be applied to MOSFET's or other heat-producing power electronic devices (including power electronic devices yet to be developed).

Although the preceding description contains significant detail, it should not be construed as limiting the scope of the invention but rather as providing illustrations of the preferred embodiments of the invention. As an example, many different shapes could be used for the containment. Thus, the scope of the invention should be fixed by the claims, rather than by the examples given.

Having described my intention, I claim:

1. A method for cooling an IGBT during operation, comprising:
a. providing a at least one IGBT;
b. providing a containment;
c. placing said at last one IGBT within said containment;
d. providing a refrigerant, with said refrigerant being selected to have a suitable boiling point so that the heat generated by said at least one IGBT during operation will cause said refrigerant to boil;
e. flooding said containment with refrigerant so that said at least one IGBT is immersed in said refrigerant; and
f. regulating the amount of said refrigerant within said containment so that said at least one IGBT remains immersed during operation.

2. A method for cooling an IGBT as recited in claim 1 wherein said step of regulating the amount of said refrigerant within said containment is carried out by providing a valve regulating the flow of said refrigerant into said containment.

3. A method for cooling an IGBT as recited in claim 1, further comprising:
a. mounting said at least one IGBT on an IGBT board, said IGBT board having an IGBT side and a back side;
b. providing a floor in said containment; and
c. placing said IGBT board on said floor with said back side facing said floor.

4. A method for cooling an IGBT as recited in claim 3, further comprising:
a. providing a channel in said floor, with one portion of said channel being in contact with said back side of said IGBT board; and
b. forcing said coolant through said channel.

5. A method for cooling an IGBT as recited in claim 4, wherein said channel is divided into a plurality of cross flow channels.

6. A method of cooling an IGBT as recited in claim 4, wherein said channel assumes a serpentine form.

7. A method for cooling an IGBT as recited in claim 3, further comprising:
a. providing a coolant manifold having at least one injector;
b. forcing said coolant through said coolant manifold and out said injector; and
c. placing said coolant manifold so that said injector directs said coolant onto said IGBT.

8. A method as recited in claim 3, wherein said IGBT board is placed in a horizontal orientation.

9. A method as recited in claim 3, wherein said IGBT board is placed in a vertical orientation.

10. A method as recited in claim 4, wherein said IGBT board is placed in a horizontal orientation.

11. A method as recited in claim 4, wherein said IGBT board is placed in a vertical orientation.

12. A method as recited in claim 5, wherein said IGBT board is placed in a horizontal orientation.

13. A method as recited in claim 5, wherein said IGBT board is placed in a vertical orientation.

14. A method as recited in claim 6, wherein said IGBT board is placed in a horizontal orientation.

15. A method as recited in claim 6, wherein said IGBT board is placed in a vertical orientation.

16. A method as recited in claim 7, wherein said IGBT board is placed in a horizontal orientation.

17. A method as recited in claim 7, wherein said IGBT board is placed in a vertical orientation.

18. A method for cooling a plurality of IGBT's during operation, comprising:
a. providing a plurality of IGBT's;
b. mounting said plurality of IGBT's on a common IGBT board, said IGBT board having an IGBT side and a back side;
c. providing a containment;
d. placing said IGBT board within said containment;
e. providing a refrigerant, with said refrigerant being selected to have a suitable boiling point so that the heat generated by said plurality of IGBT's during operation will cause said refrigerant to boil;
f. flooding said containment with refrigerant so that said plurality of IGBT's are immersed in said refrigerant; and
g. regulating the amount of said refrigerant within said containment so that said plurality of IGBT's remains immersed during operation.

19. A method for cooling an IGBT as recited in claim 18, further comprising:
a. providing a floor in said containment;
b. placing said IGBT board on said floor with said back side facing said floor;
c. providing a channel in said floor, with one portion of said channel being in contact with said back side of said IGBT board; and
d. forcing said coolant through said channel.

20. A method for cooling an IGBT as recited in claim 18, further comprising:
a. providing a coolant manifold having a plurality of injectors;
b. forcing said coolant through said coolant manifold and out said injectors; and
c. placing said coolant manifold so that said injectors direct said coolant onto said IGBT's.
